(19) United States
(12) Patent Application Publication
(10) Pub. No.: US 2025/0246505 A1
(43) Pub. Date: Jul. 31, 2025

(54) SEMICONDUCTOR PACKAGE AND METHOD FOR MAKING THE SAME

(71) Applicant: STATS ChipPAC Pte. Ltd., Singapore (SG)

(72) Inventors: YongMoo SHIN, Incheon (KR); HeeSoo LEE, Incheon (KR); SuJeong KWON, Incheon (KR)

(21) Appl. No.: 19/011,470

(22) Filed: Jan. 6, 2025

(30) Foreign Application Priority Data
Jan. 10, 2024 (CN) 202410035125.1

(51) Int. Cl. H01L 23/367; H01L 21/48; H01L 23/00; H01L 23/373; H01L 25/18; H10B 80/00; H10D 80/30

(52) U.S. Cl. CPC H01L 23/3675; H01L 21/4875; H01L 23/3677; H01L 23/3733; H01L 25/18; H01L 24/08; H01L 24/16; H01L 24/80; H01L 2224/08145; H01L 2224/16225; H01L 2224/80895; H01L 2224/80896; H01L 2225/06517; H01L 2225/06589; H01L 2924/1611; H10B 80/00; H10D 80/30

(57) ABSTRACT

A semiconductor package and a method for making the same are provided. The semiconductor package includes: a primary semiconductor die; an auxiliary semiconductor die attached onto a top surface of the primary semiconductor die; a first thermally conductive layer formed on a top surface of the auxiliary semiconductor die, wherein the first thermally conductive layer includes graphene-coated metallic particles; and a heat spreader thermally coupled with a top surface of the first thermally conductive layer.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. In order to meet the needs of consumers, more and more electronic components are tightly integrated within a single device or package. Yet, due to the tight integration, heat generated from an electronic component may be blocked by other electronic components within the same package, rendering unsatisfactory heat dissipation, and thus the performance of the semiconductor package may be impacted. Therefore, a need exists for a semiconductor package with improved heat dissipation.

### SUMMARY OF THE INVENTION

An objective of the present application is to provide a semiconductor package with improved heat dissipation.

According to an aspect of the present application, a semiconductor package is provided. The semiconductor package may include: a primary semiconductor die; an auxiliary semiconductor die attached onto a top surface of the primary semiconductor die; a first thermally conductive layer formed on a top surface of the auxiliary semiconductor die, wherein the first thermally conductive layer includes graphene-coated metallic particles; and a heat spreader thermally coupled with a top surface of the first thermally conductive layer.

According to another aspect of the present application, a method for forming a semiconductor package is provided. The method may include: providing a semiconductor die stack including a primary semiconductor die and an auxiliary semiconductor die, wherein the auxiliary semiconductor die is attached onto a top surface of the primary semiconductor die; forming a first thermally conductive layer on a top surface of the auxiliary semiconductor die, wherein the first thermally conductive layer includes graphene-coated metallic particles; and attaching a heat spreader onto the semiconductor die stack through the first thermally conductive layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view of a conventional semiconductor package.

FIG. 2A is a cross-sectional view of a semiconductor package according to an embodiment of the present application.

FIG. 2B is an enlarged view of a portion of the semiconductor package shown in FIG. 2A.

FIG. 3 is a cross-sectional view of a semiconductor package according to another embodiment of the present application.

FIG. 4 is a cross-sectional view of a semiconductor package according to another embodiment of the present application.

FIG. 5 is a cross-sectional view of a semiconductor package according to another embodiment of the present application.

FIGS. 6A to 6E are cross-sectional views illustrating various steps of a method for forming a semiconductor package according to an embodiment of the present application.

FIGS. 7A to 7C are cross-sectional views illustrating various steps of a method for forming a semiconductor package according to another embodiment of the present application.

FIGS. 8A to 8D are cross-sectional views illustrating various steps of a method for forming a semiconductor package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

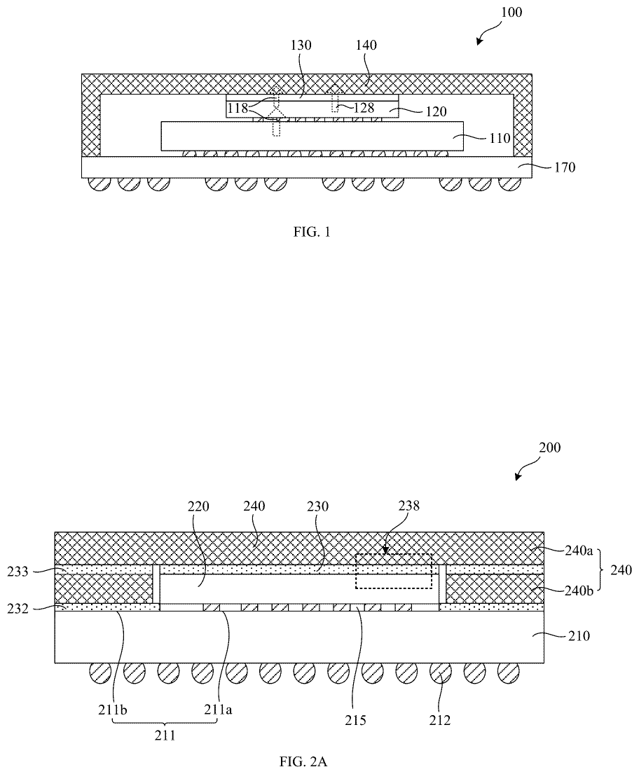

FIG. 1 is a cross-sectional view of a semiconductor package 100 having a semiconductor die stack. Specifically, the semiconductor package 100 includes a first semiconductor die 110 mounted to a substrate 170, and a second semiconductor die 120 stacked above the first semiconductor die 110. In order to dissipate heat generated by the semiconductor package 100 during operation, the semiconductor die stack is thermally coupled to a heat spreader (HS) 140 through a thermal interface material (TIM) layer 130, such that the heat 118 generated by the first semiconductor die 110 and the heat 128 generated by the second semiconductor die 120 can be transferred to the heat spreader 140 and further to the external environment. However, as shown in FIG. 1, the second semiconductor die 120 which is used as a pathway for the heat 118 generated by the first semiconductor die 110 may block dissipation of the heat 118 because the material (e.g., silicon) of the second semiconductor die 120 may not have an ideal thermal conductivity. Thus, the performance of the semiconductor package 100 may be negatively impacted due to the poor heat dissipation.

To address the above problem, a new semiconductor package is provided in an aspect of the present application. In the semiconductor package, graphene-coated metallic particles, for example, graphene-coated copper (Cu@Gr) particles, are introduced into a thermal interface material (TIM), and then the TIM is applied between a semiconductor die stack and a heat spreader. As graphene has a thermal conductivity ranging from 900 W/mK to 6500 W/mK, which is much higher than that of copper (i.e., 401 W/mK), and can prevent copper from oxidation, the thermal conductivity of the TIM layer can be significantly improved compared with conventional TIM which does not have such particles. Thus, heat can be transferred from the semiconductor die stack to the heat spreader through the TIM layer more efficiently, and the semiconductor package can have an improved heat dissipation performance.

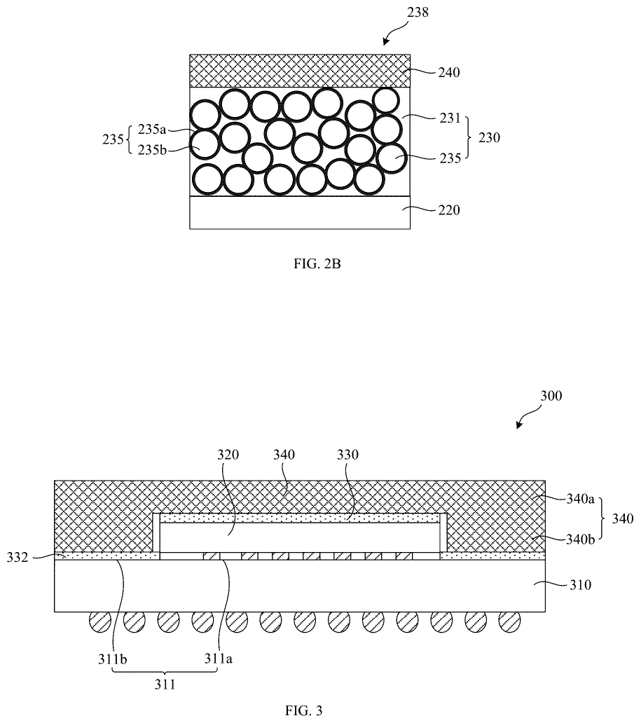

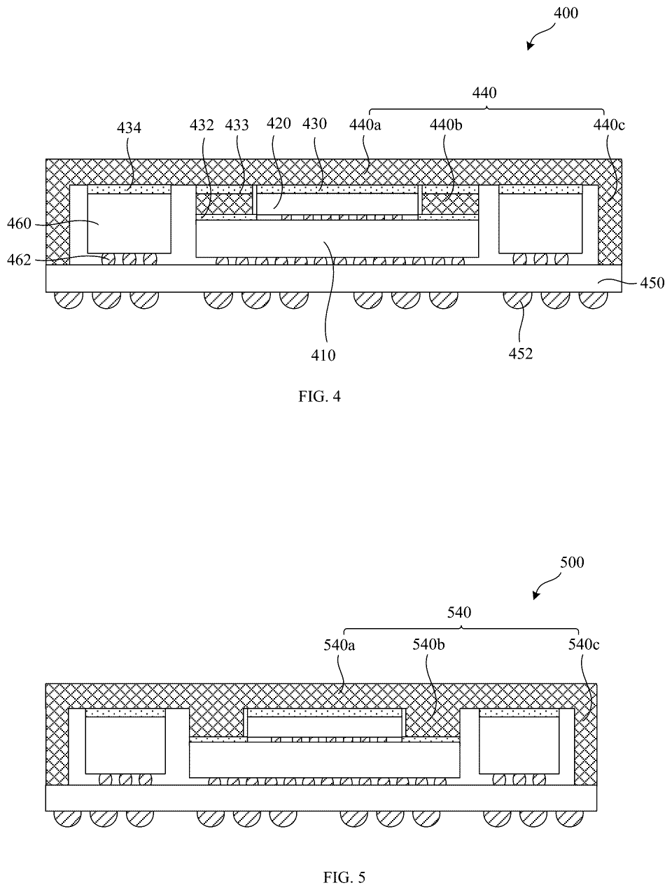

FIG. 2A illustrates a cross-sectional view of a semiconductor package 200 according to an embodiment of the present application. The semiconductor package 200 includes a semiconductor die stack including a primary semiconductor die 210 and an auxiliary semiconductor die 220, and the semiconductor die stack is thermally coupled to a heat spreader 240 through a first thermally conductive layer (also referred to as a TIM layer) 230 including graphene-coated metallic particles.

As shown in FIG. 2A, the auxiliary semiconductor die 220 is attached to a first region 211a of a top surface 211 of the primary semiconductor die 210, and the auxiliary semiconductor die 220 does not cover a second region 211b of the top surface 211 of the primary semiconductor die 210. The primary semiconductor die 210 and/or the auxiliary semiconductor die 220 may include a logic chip, a microcontroller, a microprocessor, a network processor, a power management processor, an audio processor, a video processor, a digital signal processor (DSP), an application specific integrated circuit (ASIC), a radio frequency circuit, a wireless baseband system on chip (SoC) processor, a sensor, a memory controller, a memory device, etc. In a specific example, the primary semiconductor die 210 may be a logic chip and the auxiliary semiconductor die 220 may be a memory chip. However, the present application is not limited to the above examples. In some other embodiments, there may be more than one auxiliary semiconductor dies vertically bonded on the primary semiconductor die.

The primary semiconductor die 210 and the auxiliary semiconductor die 220 are bonded together by an interconnection layer 215. In some embodiments, the primary semiconductor die 210 and the auxiliary semiconductor die 220 are bonded together by hybrid bonding, and the interconnection layer 215 may include a dielectric material and conductive interconnect structures extending through the dielectric material and between the primary semiconductor die 210 and the auxiliary semiconductor die 220. For example, the conductive interconnect structures may include copper posts, and electrically couple with through silicon vias (TSVs) formed in the primary semiconductor die 210. However, the present application is not limited to the above embodiments. In other embodiments, the interconnection layer 215 may include a ball grid array (BGA) or other suitable interconnection structures.

In addition, the primary semiconductor die 210 may include a plurality of conductive bumps 212 formed on its bottom surface. In the example shown in FIG. 2A, the conductive bumps 212 are illustrated as solder bumps, but the present application is not limited thereto. In some other embodiments, the conductive bumps 212 may include conductive pillars, or copper balls. In a case where the semiconductor package 200 is mounted on an external device or substrate such as a printed circuit board (PCB), the conductive bumps 212 may be used for electrically connecting the semiconductor package 200 to the external device or substrate.

Referring to FIG. 2A, the first thermally conductive layer 230 is formed between the auxiliary semiconductor die 220 and the heat spreader 240 for thermally coupling the semiconductor die stack with the heat spreader 240. Referring to FIG. 2B, which is an enlarged view of a portion 238 of the semiconductor package 200 shown in FIG. 2A, the first thermally conductive layer 230 may include a matrix 231 and graphene-coated metallic particles 235 dispersed in the matrix 231. In some cases, the matrix 231 may include a thermosetting material. The thermosetting material may include resin materials such as epoxies, polyimides, siloxanes, polyimide siloxanes, phenoxys, polystyrene allyl alcohol polymers, or bio-based resins, or other thermosetting resinous materials known in the art. In some cases, the matrix 231 may include a soldering material. The soldering material may include Sn, In, InAg or other suitable materials. In some embodiments, the first thermally conductive layer 230 may further include a binder material to allow the graphene-coated metallic particles to be bonded to one another and to be bonded to the matrix. In some embodiments, the first thermally conductive layer 230 may further include fillers such as silicon particles to improve structural characteristics of the first thermally conductive layer 230.

As shown in FIG. 2B, each graphene-coated metallic particle 235 may include a shield layer 235a made of graphene and a core 235b made of a metallic particle. The graphene can cover and protect the metallic particle and enhance its thermal, structural, and/or conductive properties. In an example, the graphene-coated metallic particles 235 may include graphene-coated copper particles. That is, the core 235b is made of a copper particle. It is known that copper is inexpensive and has a high thermal conductivity (e.g., 401 W/mK), but can be easily oxidized in the atmosphere. Graphene is a nanostructure carbon material exhibiting a unique structure of two-dimensional sheet. For example, the thermal conductivity of graphene may range from 900 W/mK to 6500 W/mK, for example, about 4000-5000 W/mK. On the other hand, graphene also has a superior mechanical strength, and its hardness is 200 times greater than steel. Thus, by coating the copper particles with graphene, graphene can serve as a shield to protect the copper particles from oxidation and enhance the thermal conductivity of the TIM. Consequently, the thermal conductivity of the first thermally conductive layer 230 can be improved by the graphene-coated copper particles, and more heat can be transferred from the semiconductor die stack to the heat spreader 240.

However, the present application is not limited to the above example. In some embodiments, the core 235b of the graphene-coated metallic particle 235 may include aluminum, silver, or other suitable metal material. In some embodiments, there may be an adhesion layer and/or a wetting layer formed between the first thermally conductive layer 230 and the auxiliary semiconductor die 220.

Further, as shown in FIG. 2A, the heat spreader 240 is thermally coupled with a top surface of the first thermally conductive layer 230. The heat spreader 240 at least partially surrounds the semiconductor die stack of the primary semiconductor die 210 and the auxiliary semiconductor die 220, so as to dissipate heat from the semiconductor package 200. The heat spreader 240 may include copper, aluminum, nickel-plated copper, nickel-plated aluminum, or other materials with a high thermal conductivity.

In the embodiment shown in FIG. 2A, the heat spreader 240 includes a lid 240a and a first plurality of lateral portions 240b extending from the lid 240a. The lid 240a is disposed above the auxiliary semiconductor die 220 and is thermally coupled to the auxiliary semiconductor die 220 through the first thermally conductive layer 230. The semiconductor package 200 further includes a second thermally conductive layer 232 formed on the second region 211b of the top surface 211 of the primary semiconductor die 210, and the first plurality of lateral portions 240b of the heat spreader 240 are disposed on and thermally coupled to the second region 211b of the primary semiconductor die 210 through the second thermally conductive layer 232.

In the example shown in FIG. 2A, the lid 240a and the first plurality of lateral portions 240b are separate parts of the heat spreader 240. Further, the semiconductor package 200 includes a third thermally conductive layer 233. The third thermally conductive layer 233 is disposed between the lid 240a and the first plurality of lateral portions 240b for thermally coupling them with each other. In some embodiments, the second thermally conductive layer 232 and/or the third thermally conductive layer 233 may include the same material as the first thermally conductive layer 230. That is, the second thermally conductive layer 232 and/or the third thermally conductive layer 233 may also include a matrix and graphene-coated metallic particles dispersed in the matrix. In some embodiments, the second thermally conductive layer 232 and/or the third thermally conductive layer 233 may include materials different from the first thermally conductive layer 230, such as a soldering type or grease type thermal interface material.

It can be understood that, in some other embodiments, the heat spreader 240 may take other shapes. There may be space between the heat spreader 240 and the semiconductor dice 210 and 220. It can also be understood that, the heat spreader 240 may not include any lateral portion, or may include 1, 2, 3, 4, or more lateral portions 240b. For example, 4 lateral portions 240b may be connected to each other, forming a surrounding wall accommodating the auxiliary semiconductor die 220.

As discussed above, the semiconductor package 200 includes the thermally conductive layers 230, 232 and 233 and the heat spreader 240. Since the thermally conductive layers 230, 232 and 233 containing the graphene-coated copper particles have a higher thermal conductivity than conventional thermal interface materials, heat generated by the semiconductor die stack can be more efficiently and quickly transferred through the thermally conductive layers 230, 232 and 233 to the heat spreader 240. Therefore, the thermal dissipation of the semiconductor package 200 may be improved compared to conventional packages.

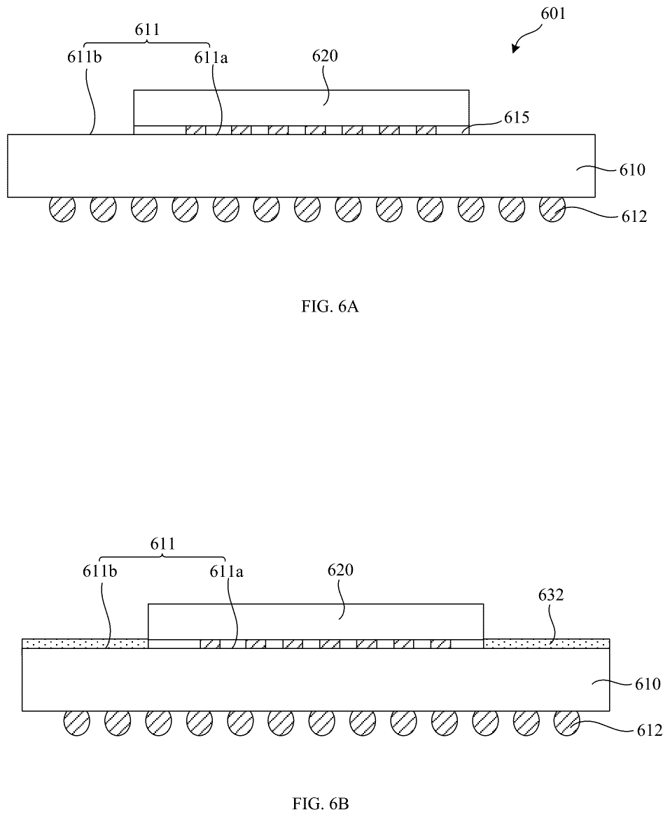

Referring to FIG. 3, a semiconductor package 300 is illustrated according to another embodiment of the present application. The semiconductor package 300 may have some similar structures and configurations as the semiconductor package 200 shown in FIG. 2A. The similar or same parts between the semiconductor package 300 and the semiconductor package 200 will not be repeated herein.

Specifically, as shown in FIG. 3, the semiconductor package 300 includes a primary semiconductor die 310 and an auxiliary semiconductor die 320 attached on a first region 311a of a top surface 311 of the primary semiconductor die 310. A first thermally conductive layer 330 is formed on a top surface of the auxiliary semiconductor die 320 to thermally couple the auxiliary semiconductor die 320 with a heat spreader 340. The first thermally conductive layer 330 may include a matrix (for example, a thermosetting material or a soldering material) and graphene-coated metallic particles dispersed in the matrix. The semiconductor package 300 further includes a second thermally conductive layer 332 formed on a second region 311b of the top surface 311 of the primary semiconductor die 310. The heat spreader 340 includes a lid 340a and a first plurality of lateral portions 340b. The lid 340a is disposed on and thermally coupled to the auxiliary semiconductor die 320 through the first thermally conductive layer 330, and the first plurality of lateral portions 340b are disposed on and thermally coupled to the second region 311b of the top surface 311 of the primary semiconductor die 310 through the second thermally conductive layer 332. Different from the semiconductor package 200 shown in FIG. 2A, the lid 340a and the first plurality of lateral portions 340b of the semiconductor package 300 in FIG. 3 are integrally formed as a single piece, and thus no other support or heat transfer component is desired between the lateral portions 340b and the lid 340a of the heat spreader 340.

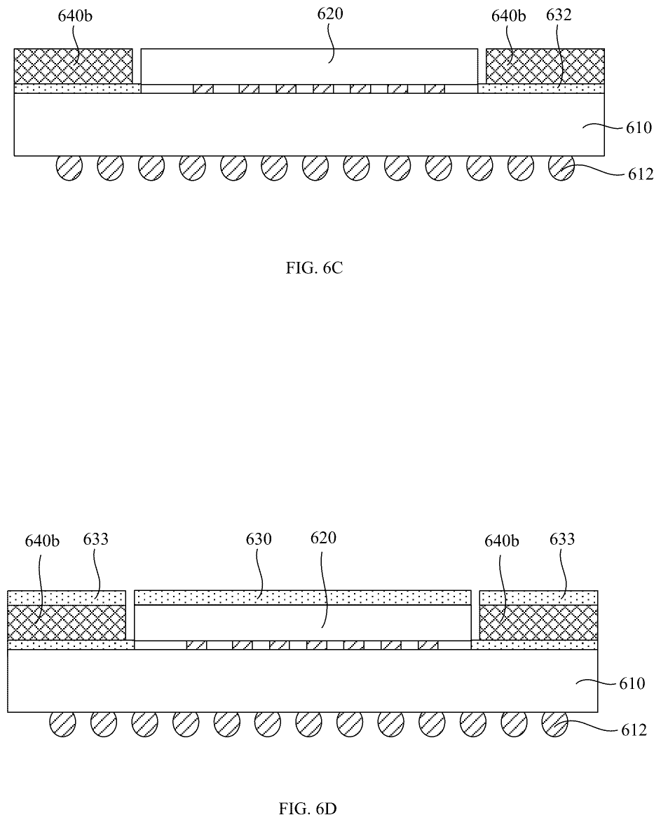

Referring to FIG. 4, a semiconductor package 400 is illustrated according to another embodiment of the present application. The semiconductor package 400 may have some similar structures and configurations as the semiconductor package 200 shown in FIG. 2A. The similar or same parts between the semiconductor package 400 and the semiconductor package 200 will not be repeated herein.

Specifically, as shown in FIG. 4, the semiconductor package 400 includes a primary semiconductor die 410 and an auxiliary semiconductor die 420 attached on a first region of a top surface of the primary semiconductor die 410. A first thermally conductive layer 430 is formed on a top surface of the auxiliary semiconductor die 420 to thermally couple the auxiliary semiconductor die 420 with a heat spreader 440. The first thermally conductive layer 430 may include a matrix (for example, a thermosetting material or a soldering material) and graphene-coated metallic particles dispersed in the matrix. The semiconductor package 400 further includes a second thermally conductive layer 432 formed on a second region of the top surface of the primary semiconductor die 410. The heat spreader 440 includes a lid 440a, a first plurality of lateral portions 440b, and a second plurality of lateral portions 440c. In this example, the first plurality of lateral portions 440b are separated from the lid 440a, but the second plurality of lateral portions 440c and the lid 440a are integrally formed as a single piece. The first plurality of lateral portions 440b are thermally coupled with the lid 440a through a third thermally conductive layer 433. The second plurality of lateral portions 440c are spaced apart from the first plurality of lateral portions 440b to form at least one cavity therebetween.

Moreover, the semiconductor package 400 shown in FIG. 4 further includes a substrate 450 and one or more electronic components 460 received within the cavity between the first plurality of lateral portions 440b and the second plurality of lateral portions 440c of the heat spreader 440. The substrate 450 can support the semiconductor die stack of the primary semiconductor die 410 and the auxiliary semiconductor die 420 and the electronic components 460. For example, the primary semiconductor die 410 is attached on a top surface of the substrate 450 via the conductive bumps formed on the bottom surface of the primary semiconductor die 410. Further, the substrate 450 can provide electrical connections for the primary semiconductor die 410 and the electronic components 460 mounted on the substrate 450. The substrate 450 may include a plurality of conductive bumps 452 formed on its bottom surface, and the conductive bumps 452 can be used for electrically connecting the semiconductor package 400 to an external device or substrate.

As shown in FIG. 4, the lid 440a of the heat spreader 440 is disposed on and thermally coupled to the auxiliary semiconductor die 420 through the first thermally conductive layer 430, the first plurality of lateral portions 440b are disposed on and thermally coupled to the second region of the top surface of the primary semiconductor die 410 through the second thermally conductive layer 432, and the second plurality of lateral portions 440c are disposed on and thermally coupled to a top surface of the substrate 450 by any suitable techniques. The second plurality of lateral portions 440c may be connected to each other, forming a surrounding wall accommodating the electronic components 460. The electronic components 460 may include any of a variety of types of semiconductor dice, semiconductor packages, or discrete devices. For example, the electronic components 460 may include a high-bandwidth memory (HBM). The electronic components 460 may be mounted on the substrate 450 via a plurality of interconnection structures, such as the solder balls 462 shown in FIG. 4. Moreover, the semiconductor package 400 further includes a fourth thermally conductive layer 434 disposed between the lid 440a and the electronic components 460 for thermally coupling them with each other. The second thermally conductive layer 432, the third thermally conductive layer 433, or the fourth thermally conductive layer 434 may include a material the same as or different from that of the first thermally conductive layer 430.

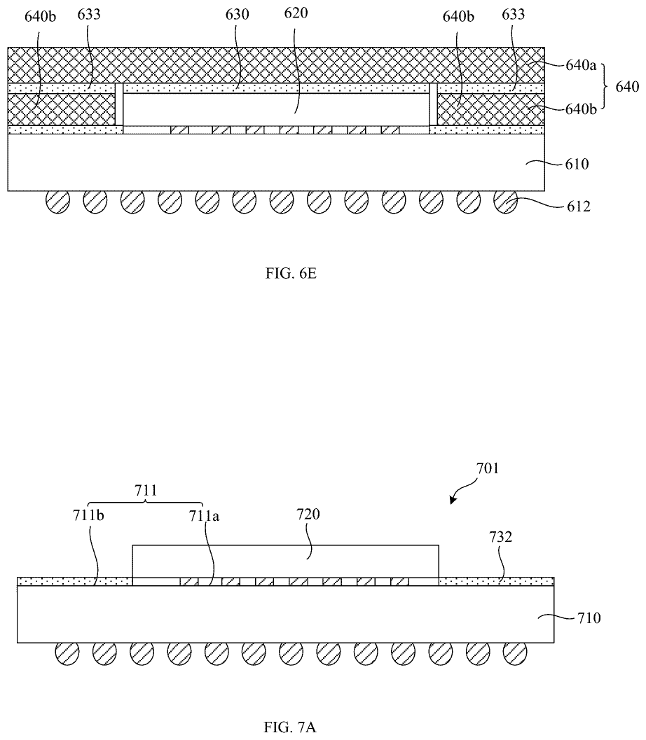

Referring to FIG. 5, a semiconductor package 500 is illustrated according to another embodiment of the present application. The semiconductor package 500 may have some similar structures and configurations as the semiconductor package 400 shown in FIG. 4. The similar or same parts between the semiconductor package 500 and the semiconductor package 400 will not be repeated herein.

The semiconductor package 500 shown in FIG. 5 is different from the semiconductor package 400 shown in FIG. 4 in that a heat spreader 540 of the semiconductor package 500 has a different configuration from the semiconductor package 400. Specifically, the heat spreader 540 includes a lid 540a, a first plurality of lateral portions 540b, and a second plurality of lateral portions 540c. In this example, all the lid 540a, the first plurality of lateral portions 540b and the second plurality of lateral portions 540c are integrally formed as a single piece.

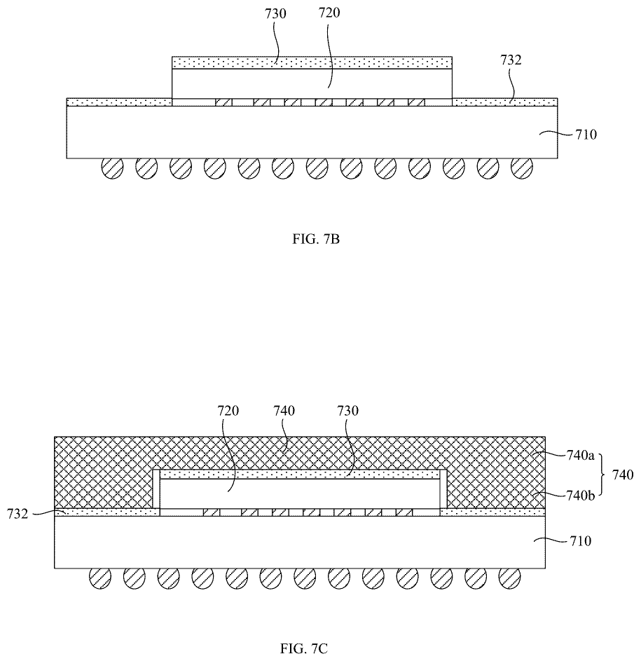

Referring to FIGS. 6A to 6E, various steps of a method for forming a semiconductor package are illustrated according to an embodiment of the present application. For example, the method may be used to form the semiconductor package 200 shown in FIG. 2A. In the following, the method will be described with reference to FIGS. 6A to 6E in more details.

Referring to FIG. 6A, a semiconductor die stack 601 is provided. The semiconductor die stack 601 includes a primary semiconductor die 610 and an auxiliary semiconductor die 620.

Specifically, the primary semiconductor die 610 includes a top surface 611 with a first region 611a and a second region 611b besides the first region 611a. The auxiliary semiconductor die 620 is attached onto the first region 611a of the top surface 611 of the primary semiconductor die 610. The primary semiconductor die 610 and the auxiliary semiconductor die 620 are bonded together by an interconnection layer 615. For example, the primary semiconductor die 610 and the auxiliary semiconductor die 620 are bonded together by hybrid bonding, and the interconnection layer 615 may include a dielectric material and conductive interconnect structures extending through the dielectric material and between the primary semiconductor die 610 and the auxiliary semiconductor die 620. In addition, the primary semiconductor die 610 may include a plurality of conductive bumps 612 formed on its bottom surface.

Referring to FIG. 6B, a thermally conductive layer 632 is formed on the second region 611b of the top surface 611 of the primary semiconductor die 610. The thermally conductive layer 632 may correspond to the second thermally conductive layer 232 of the semiconductor package 200 shown in FIG. 2A.

In some embodiments, the thermally conductive layer 632 may include graphene-coated metallic particles. Specifically, a jet printing method may be used to print a fluid including a matrix (for example, a thermosetting material or a soldering material) and the graphene-coated metallic particles dispersed therein onto the second region 611b of the top surface 611 of the primary semiconductor die 610 to form the thermally conductive layer 632. In some cases, when the fluid includes the soldering material, a metal coating may be first formed on the second region 611b of the top surface 611 to facilitate printing of the fluid.

For example, an aerosol jetting apparatus may be used to print the fluid on the second region 611b of the top surface 611 of the primary semiconductor die 610. The aerosol jetting apparatus can atomize the fluid (including the matrix and the graphene-coated metallic particles) via ultrasonic or pneumatic means, so as to produce droplets on the order of one to more micrometers in diameter. The droplets may be entrained in a gas stream and delivered to a print head. At the print head, a sheath gas flow (for example, N₂ gas flow) may be introduced to focus the droplets into a tightly collimated beam of material. Then, the combined gas streams may fly out of the print head through a converging nozzle that compresses the aerosol stream to particles or droplets with a small diameter. Then, the jet of droplets may fly out of the print head at a high velocity and impinge upon the top surface 611 of the primary semiconductor die 610. Thus, the thermally conductive layer 632 can be formed by moving the print head of the aerosol jetting apparatus and continuously dispensing the droplets. In another example, an electrohydrodynamic (EHD) jetting apparatus may be used to print the fluid on the second region 611b of the top surface 611 of the primary semiconductor die 610. The EHD jetting apparatus can generate very fine droplets of the fluid by applying an electric field between its nozzle and the top surface 611 of the primary semiconductor die 610, so as to emit a jet of droplets of the fluid on top surface 611 of the primary semiconductor die 610 to form the thermally conductive layer 632. Both the aerosol jetting apparatus and the EHD jetting apparatus can easily and accurately control the position and/or the dispensing time of the jet of droplets, and thus the thermally conductive layer 632 can be directly formed at a desired area with a desired shape without any mask, or any photolithography process.

However, the present application is not limited to the embodiments described above. In some other embodiments, the thermally conductive layer 632 may include a soldering type or grease type thermal interface material, and may be dispensed, sprayed or printed on the second region 611b of the top surface 611 of the primary semiconductor die 610 by jet printing, laser printing, pneumatically, or any other deposition process, which can form the thermally conductive layer 632 directly at a desired area with a desired shape.

Afterwards, referring to FIG. 6C, a plurality of lateral portions 640b of a heat spreader are attached on the thermally conductive layer 632 through the thermally conductive layer 632.

In some embodiments, a top surface of each lateral portion 640b is substantially flush or coplanar with a top surface of the auxiliary semiconductor die 620. In some embodiments, the lateral portions 640b are connected with each other to fully or partially surround the auxiliary semiconductor die 620. The lateral portions 640b may include copper, aluminum, nickel-plated copper, nickel-plated aluminum, or other materials with a high thermal conductivity. In some embodiments, after the lateral portions 640b of a heat spreader are disposed on the thermally conductive layer 632, the fluid forming the thermally conductive layer 632 may be cured or solidified to attach the lateral portions 640b to the top surface 611 of the primary semiconductor die 610.

Afterwards, referring to FIG. 6D, a thermally conductive layer 630 is formed on a top surface of the auxiliary semiconductor die 620, and another thermally conductive layer 633 is formed on a top surface of each lateral portion 640b of the heat spreader. The thermally conductive layer 630 and the thermally conductive layer 633 may correspond to the first second thermally conductive layer 230 and the third thermally conductive layer 233 of the semiconductor package 200 shown in FIG. 2A, respectively.

In some embodiments, a top surface of the thermally conductive layer 630 may be substantially flush or coplanar with a top surface of the thermally conductive layer 633. The thermally conductive layer 630 may include graphene-coated metallic particles. For example, the jet printing method described above with reference to FIG. 6B can also be used to form the thermally conductive layer 630 on the top surface of the auxiliary semiconductor die 620, and will not be elaborated herein.

In some embodiments, the thermally conductive layer 633 may include a material the same as the thermally conductive layer 630, i.e., graphene-coated metallic particles, or may include materials different from the thermally conductive layer 630, such as soldering type or grease type thermal interface material. The thermally conductive layer 633 can be formed on the top surface of the lateral portion 640b by jet printing, laser printing, pneumatically, or any other suitable deposition process.

At last, referring to FIG. 6E, a lid 640a of the heat spreader 640 is attached on the top surface of the thermally conductive layer 630 and the top surface of the thermally conductive layer 633. After that, the lid 640a is thermally coupled to the auxiliary semiconductor die 620 through the thermally conductive layer 630, and is thermally coupled to the lateral portions 640b of the heat spreader 640 through the thermally conductive layer 633. The material of the lid 640a may be the same as or different from the lateral portions 640b of the heat spreader 640. Further, when the thermally conductive layers 630 and 633 are formed by the fluid including the matrix and the graphene-coated metallic particles, the thermally conductive layers 630 and 633 may be cured or solidified after the lid 640a of the heat spreader 640 is attached thereon.

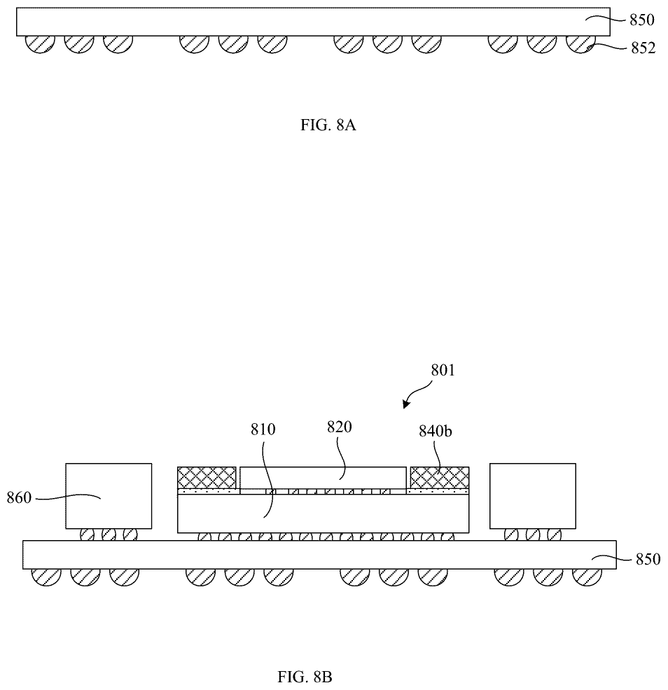

Referring to FIGS. 7A to 7C, various steps of a method for forming a semiconductor package are illustrated according to another embodiment of the present application. For example, the method may be used to form the semiconductor package 300 shown in FIG. 3. Different from the embodiment described with reference to FIGS. 6A-6E, the lid and the lateral portions of the heat spreader in this embodiment are integrally formed as a single piece.

Referring to FIG. 7A, a package 701 is provided. The package 701 includes a primary semiconductor die 710 and an auxiliary semiconductor die 720 stacked on a first region 711a of a top surface 711 of the primary semiconductor die 710. A thermally conductive layer 732 is formed on a second region 711b of the top surface 711 of the primary semiconductor die 710. The package 701 shown in FIG. 7A is similar to the structure shown in FIG. 6B, and will not be elaborated herein.

Afterwards, referring to FIG. 7B, a thermally conductive layer 730 is formed on a top surface of the auxiliary semiconductor die 720. The thermally conductive layer 730 may include graphene-coated metallic particles. It could be understood that, the thermally conductive layer 730 and the thermally conductive layer 732 can be formed simultaneously or in different steps.

Afterwards, referring to FIG. 7C, a heat spreader 740 is attached to the semiconductor die stack including the primary semiconductor die 710 and the auxiliary semiconductor die 720. Specifically, the heat spreader 740 includes a lid 740a and a first plurality of lateral portions 740b extending from the lid 740a, and the lid 740a and the lateral portions 740b are integrally formed as a single piece. Thus, the lid 740a is thermally coupled to the top surface of the auxiliary semiconductor die 720 through the thermally conductive layer 730, and the lateral portions 740b are thermally coupled to the top surface of the primary semiconductor die 710 through the thermally conductive layer 732.

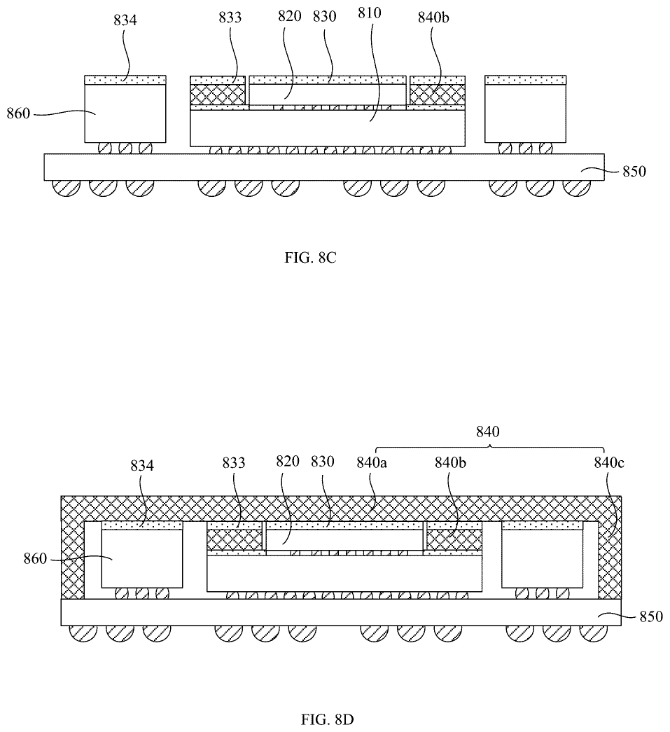

Referring to FIGS. 8A to 8D, various steps of a method for forming a semiconductor package are illustrated according to another embodiment of the present application. For example, the method may be used to form the semiconductor package 400 shown in FIG. 4.

Referring to FIG. 8A, a substrate 850 is provided. The substrate 850 can support and provide electrical connections for semiconductor dice or electronic components mounted thereon. The substrate 850 may further include a plurality of conductive bumps 852 formed on its bottom surface.

Afterwards, referring to FIG. 8B, a package 801 and one or more electronic components 860 are mounted on a top surface of the substrate 850. The package 801 includes a primary semiconductor die 810 and an auxiliary semiconductor die 820 stacked on a top surface of the primary semiconductor die 810. A first plurality of lateral portions 840b of a heat spreader are also attached on the top surface of the primary semiconductor die 810 through a thermally conductive layer. The package 801 shown in FIG. 8B is similar to the structure shown in FIG. 6C, and will not be elaborated herein. The electronic components 860 may include any of a variety of types of semiconductor dice, semiconductor packages, or discrete devices. For example, the electronic components 860 may include a high-bandwidth memory (HBM). The package 801 and/or the electronic components 860 may be mounted on the substrate 850 via a plurality of interconnection structures, such as the solder balls shown in FIG. 8B.

Afterwards, referring to FIG. 8C, a thermally conductive layer 830 is formed on a top surface of the auxiliary semiconductor die 820, a thermally conductive layer 833 is formed on a top surface of each lateral portion 840b of the heat spreader, and a thermally conductive layer 834 is formed on a top surface of each electronic component 860. The thermally conductive layers 830, 833 and 834 may include graphene-coated copper particles, and the top surfaces of the thermally conductive layers 830, 833 and 834 may at the same height. For example, the jet printing method described above with reference to FIG. 6B may be used to form the thermally conductive layers 830, 833 and 834.

At last, referring to FIG. 8D, a lid 840a of the heat spreader 840 is attached on the top surfaces of the thermally conductive layers 830, 833 and 834. Thus, the lid 840a of the heat spreader 840 is thermally coupled to the auxiliary semiconductor die 820, the first plurality of lateral portions 840b and the electronic components 860 through the thermally conductive layers 830, 833 and 834, respectively. In this embodiment, the heat spreader 840 further includes a second plurality of lateral portions 840c extending from the lid 840a, and the second plurality of lateral portions 840c are disposed on and thermally coupled to the top surface of the substrate 850 by any suitable techniques.

While different processes for forming semiconductor packages are illustrated in conjunction with FIGS. 6A-6E, FIGS. 7A-7C and FIGS. 8A-8D, it will be appreciated by those skilled in the art that modifications and adaptations to the processes may be made without departing from the scope of the present invention. For example, although it is illustrated in FIG. 8D that the lid and the first plurality of lateral portions are separate parts of the heat spreader, the lid and the first plurality of lateral portions can be integrally formed as a single piece, and the semiconductor device 500 shown in FIG. 5 can be formed by the same or similar processes described with reference to FIGS. 8A-8D.

The discussion herein included numerous illustrative figures that showed various portions of a semiconductor package and a method for making the same. For illustrative clarity, such figures did not show all aspects of each example package. Any of the example packages and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a primary semiconductor die;
an auxiliary semiconductor die attached onto a top surface of the primary semiconductor die;
a first thermally conductive layer formed on a top surface of the auxiliary semiconductor die, wherein the first thermally conductive layer comprises graphene-coated metallic particles; and
a heat spreader thermally coupled with a top surface of the first thermally conductive layer.

2. The semiconductor package of claim 1, wherein the first thermally conductive layer further comprises a matrix comprising a thermosetting material or a soldering material, the graphene-coated metallic particles is dispersed in the matrix, and the graphene-coated metallic particles comprise graphene-coated copper particles.

3. The semiconductor package of claim 1, wherein the top surface of the primary semiconductor die comprises a first region and a second region besides the first region, and the auxiliary semiconductor die is attached onto the first region of the top surface of the primary semiconductor die; and
wherein the semiconductor package further comprises:
a second thermally conductive layer formed on the second region of the top surface of the primary semiconductor die, wherein the heat spreader is thermally coupled to the primary semiconductor die through the second thermally conductive layer.

4. The semiconductor package of claim 1, wherein the heat spreader comprises:
a lid disposed onto and thermally coupled to the auxiliary semiconductor die through the first thermally conductive layer; and
a first plurality of lateral portions disposed onto and thermally coupled to the second region of the top surface of the primary semiconductor die through the second thermally conductive layer.

5. The semiconductor package of claim 4, further comprising:
a third thermally conductive layer disposed between the lid and the first plurality of lateral portions for thermally coupling them with each other.

6. The semiconductor package of claim 4, wherein the lid and the first plurality of lateral portions are integrally formed as a single piece.

7. The semiconductor package of claim 4, further comprising:
a substrate, wherein the primary semiconductor die is attached onto a top surface of the substrate; and
wherein the heat spreader further comprises:
a second plurality of lateral portions extends between the lid and the substrate.

8. The semiconductor package of claim 7, wherein the second plurality of lateral portions are spaced apart from the first plurality of lateral portions to form at least one cavity therebetween, and
wherein the semiconductor package further comprises:
at least one electronic component received within the cavity and attached onto the top surface of the substrate.

9. The semiconductor package of claim 8, further comprising:
a fourth thermally conductive layer disposed between the lid and the at least one electronic component for thermally coupling them with each other,
wherein the second thermally conductive layer, the third thermally conductive layer, or the fourth thermally conductive layer comprises the graphene-coated metallic particles.

10. A method for forming a semiconductor package, comprising:
providing a semiconductor die stack comprising a primary semiconductor die and an auxiliary semiconductor die, wherein the auxiliary semiconductor die is attached onto a top surface of the primary semiconductor die;
forming a first thermally conductive layer on a top surface of the auxiliary semiconductor die, wherein the first thermally conductive layer comprises graphene-coated metallic particles; and
attaching a heat spreader onto the semiconductor die stack through the first thermally conductive layer.

11. The method of claim 10, wherein forming the first thermally conductive layer comprises:
printing a fluid comprising a matrix and the graphene-coated metallic particles dispersed therein onto the top surface of the auxiliary semiconductor die by an electrohydrodynamic (EHD) jetting apparatus or an aerosol jetting apparatus, the matrix comprising a thermosetting material or a soldering material; and
wherein the method further comprises:
curing the fluid to form the first thermally conductive layer after the heat spreader is attached onto the semiconductor die stack.

12. The method of claim 11, wherein the top surface of the primary semiconductor die comprises a first region and a second region besides the first region, and the auxiliary semiconductor die is attached onto the first region of the top surface of the primary semiconductor die; and
wherein the method further comprises:
forming a second thermally conductive layer on the second region of the top surface of the primary semiconductor die, wherein the heat spreader is thermally coupled to the primary semiconductor die through the second thermally conductive layer when the heat spreader is attached onto the semiconductor die stack.

13. The method of claim 12, wherein the heat spreader comprises a lid and a first plurality of lateral portions integrated with the lid,
wherein attaching the heat spreader onto the semiconductor die stack comprising:
attaching the lid onto the auxiliary semiconductor die through the first thermally conductive layer; and
attaching the first plurality of lateral portions onto the second region of the top surface of the primary semiconductor die through the second thermally conductive layer.

14. The method of claim 13, wherein the heat spreader further comprises a second plurality of lateral portions;
wherein the method further comprising:
providing a substrate; and
attaching the primary semiconductor die onto a top surface of the substrate; and
wherein attaching the heat spreader onto the semiconductor die stack comprising:
attaching the second plurality of lateral portions onto the top surface of the substrate.

15. The method of claim 12, wherein the heat spreader comprises a lid and a first plurality of lateral portions separated from the lid,
wherein attaching the heat spreader onto the semiconductor die stack comprising:
attaching the first plurality of lateral portions onto the second region of the top surface of the primary semiconductor die through the second thermally conductive layer;
forming a third thermally conductive layer on each of the first plurality of lateral portions; and
attaching the lid onto the auxiliary semiconductor die and the first plurality of lateral portions through the first thermally conductive layer and the third thermally conductive layer respectively.

16. The method of claim 15, wherein the heat spreader further comprises a second plurality of lateral portions;
wherein the method further comprising:
providing a substrate; and
attaching the primary semiconductor die onto a top surface of the substrate; and
wherein attaching the heat spreader onto the semiconductor die stack comprising:
attaching the second plurality of lateral portions onto the top surface of the substrate.

17. The method of claim 16, wherein the second plurality of lateral portions are spaced apart from the first plurality of lateral portions to form at least one cavity therebetween;
wherein the method further comprising:
attaching at least one electronic component onto the top surface of the substrate; and
forming a fourth thermally conductive layer on a top surface of the at least one electronic component; and
wherein attaching the heat spreader onto the semiconductor die stack comprising:
attaching the lid onto the at least one electronic component through the fourth thermally conductive layer, such that the at least one electronic component is received within the cavity between the first plurality of lateral portions and the second plurality of lateral portions.

18. The method of claim 17, wherein the first thermally conductive layer, the second thermally conductive layer, the third thermally conductive layer, or the fourth thermally conductive layer comprises graphene-coated copper particles.

19. A thermal interface material, comprising:
a matrix comprising a thermosetting material or a soldering material; and
a plurality of graphene-coated metallic particles dispersed in the matrix, wherein each of the plurality of graphene-coated metallic particles comprises a metallic core and a graphene shell covering the metallic core.

20. The thermal interface material of claim 19, wherein the metallic core comprises copper.
